(19) United States
(12) Patent Application Publication
(10) Pub. No.: US 2013/0312810 A1
(43) Pub. Date: Nov. 28, 2013

(54) SOLAR BATTERY MODULE AND MANUFACTURING METHOD THEREOF

(71) Applicants: Tsuneo Hamaguchi, Tokyo (JP); Yoshimi Yabugaki, Tokyo (JP); Shinsuke Miyamoto, Tokyo (JP); Yasumichi Hatanaka, Tokyo (JP)

(72) Inventors: Tsuneo Hamaguchi, Tokyo (JP); Yoshimi Yabugaki, Tokyo (JP); Shinsuke Miyamoto, Tokyo (JP); Yasumichi Hatanaka, Tokyo (JP)

(73) Assignee: MITSUBISHI ELECTRIC CORPORATION, Chiyoda-ku (JP)

(21) Appl. No.: 13/983,601

(22) PCT Filed: Apr. 5, 2012
(86) PCT No.: PCT/JP2012/059360

§ 371 Date: Aug. 5, 2013

(30) Foreign Application Priority Data
Apr. 11, 2011 (JP) 2011-087195

(51) Int. Cl. H01L 31/05; H01L 31/18

(52) U.S. Cl. CPC H01L 31/0504; H01L 31/18
USPC 136/244; 438/73

(57) ABSTRACT

In a solar battery module including a plurality of solar battery elements each including electrodes that are electrically connected by an electrically conductive wiring member, the electrode and the wiring member are welded by solder on the electrode, resin is arranged while covering at least a side surface of a solder-bonded portion between the solder and the electrode, and a wetted height of the resin on a side surface of the wiring member is lower than the top of wiring member, so that welding by the solder can be reinforced and the bonding reliability can be improved.

### FIELD

The present invention relates to a solar battery module and a manufacturing method thereof, and more particularly to a solar battery module including a plurality of solar battery elements electrically connected to each other by connecting electrodes of the solar battery elements by a wiring member and a manufacturing method thereof.

### BACKGROUND

A solar battery module includes a solar battery element, a light-receiving-surface-side protecting member, a rear-surface-side protecting member, and a sealing member. The light-receiving-surface-side protecting member is arranged on a side of a light-receiving surface of the solar battery element. The material for the light-receiving-surface-side protecting member includes glass or transparent plastic, for example. The rear-surface-side protecting member is arranged on a side of a rear surface of the solar battery element. The material for the rear-surface-side protecting member includes, for example, a transparent film such as PET (Polyethylene Terephthalate) or a laminated film sandwiching an Al foil.

The sealing member is arranged between the light-receiving-surface-side protecting member and the solar battery element and between the solar battery element and the rear-surface-side protecting member. The material for the sealing member includes transparent resin such as EVA (ethylene vinyl acetate copolymer), silicon, or urethane, for example.

The solar battery element typically includes the light-receiving surface that receives sunlight and the rear surface that does not receive the sunlight, and collector electrodes for bonding with the wiring member are respectively formed on both sides of the solar battery element. The wiring member alternately connects a collector electrode formed on the light-receiving surface of one solar battery element and a collector electrode formed on the rear surface of the other solar battery element adjacent to the one solar battery element. For example, as the wiring member, an electrically conductive member such as copper is used.

The solar battery element includes a photoelectric conversion portion that performs a photoelectric conversion, a thin wire electrode for collecting a photo-generated carrier from the photoelectric conversion portion, and a collector electrode for collecting the photo-generated carrier from the thin wire electrode. In order to collect the photo-generated carrier from the photoelectric conversion portion with high efficiency, for example, several tens of thin wire electrodes are formed at a regular interval across the entire area in a plane of the solar battery element. The thin wire electrode is formed by sintering an electrically conductive paste including glass or resin as a binder and electrically conductive particles of silver (Ag) as a filler, for example. An electrode width of the thin wire electrode is set as narrow as several tens of micrometers, for example, in order to increase an area of the photoelectric conversion portion.

The collector electrode has a function of bonding with the wiring member, and a few collector electrodes are formed on the solar battery element so as to intersect the thin wire electrodes. Similarly to the thin wire electrode, the collector electrode is formed by sintering an electrically conductive paste including glass or resin as a binder and electrically conductive particles of silver (Ag) as a filler, for example. The electrode width of the collector electrode is about 1 to 2 millimeters, for example.

There are two types of methods to bond the collector electrode and the wiring member. The first method is to bond the collector electrode and the wiring member with solder. The wiring member is formed by plating the solder on a surface of an electrically conductive member such as copper. The solder typically includes tin (Sn). Such a tin-based solder includes Sn-3Ag—O, 5Cu, and Sn—Cu, for example.

When the collector electrode and the wiring member are bonded by solder, a flux is applied on at least one of a surface of the collector electrode or a surface of the wiring member, in order to remove oxides or the like formed on the surface of the collector electrode and the surface of the wiring member. By bringing the wiring member and the collector electrode into contact with each other and heating them in this state, the oxides on the surface of the collector electrode and the surface of the wiring member are removed by a reduction action of the flux, by which the bonding is achieved by solder (see, for example, Patent Literature 1 and Patent Literature 2).

The second method is to bond the collector electrode and the wiring member by using a resin adhesive containing electrically conductive particles. In this case, the resin adhesive containing the electrically conductive particles such as Ni balls plated with nickel (Ni) or gold (Au) or plastic balls plated with Au is arranged on the collector electrode. For example, as the resin adhesive, a strip-shaped film containing epoxy resin as its main component is used. By brining the wiring member into contact with the collector electrode and heating them in this state, the resin adhesive is cured, by which the bonding of the wiring member and the collector electrodes is achieved (see, for example, Patent Literature 3). In this case, the physical bonding of the wiring member and the collector electrode is achieved by the resin adhesive. The electrical connection of the wiring member and the collector electrode is obtained by contact of the electrically conductive particles contained in the resin adhesive.

### CITATION LIST

### Patent Literatures

Patent Literature 1: Japanese Patent No. 4266840
Patent Literature 2: Japanese Patent Application Laid-open No. 2009-272406
Patent Literature 3: International Publication No. WO2009/011209

### SUMMARY

### Technical Problem

However, with the first method in which the collector electrode and the wiring member are bonded by solder, the flux used in soldering may be adhered to a manufacturing apparatus, so that the solar battery element is damaged. Furthermore, cracks may be generated from an end surface of a solder-bonded portion due to a difference in thermal expansion between the collector electrode and the wiring member, so that the reliability of the bonding is degraded.

Further, with the second method of using the resin adhesive, an electrical contact resistance between the wiring member and the collector electrode is about ten times larger than a case of using solder. As the electrical connection is obtained by the particles, an electrical connection area may be decreased so that an allowable current is decreased, which decreases the power generation efficiency and the photoelectric conversion efficiency. In addition, as a bonding strength between the wiring member and the collector electrode when using the resin adhesive is as small as about 1/10 of that of the case of using solder, the bonding reliability may be degraded.

The present invention has been achieved in view of the above aspects, and an object of the present invention is to provide a solar battery module and a method of manufacturing a solar battery module having excellent mechanical strength and bonding reliability between a wiring member and an electrode and excellent photoelectric conversion efficiency.

### Solution to Problem

To solve the above problem and achieve the above object, a solar battery module according to the present invention includes a plurality of solar battery elements of which collector electrodes are electrically connected by an electrically conductive wiring members, in which the collector electrode and the wiring member are welded by solder on the collector electrode and thermosetting resin is arranged while covering at least a side surface of a solder-welded boundary between solder and the collector electrode.

### Advantageous Effects of Invention

According to the present invention, an electrode and a wiring member of a solar battery element are welded by solder, and resin covers a side surface of a solder-welded portion, and thus it is possible to suppress development of cracks from a solder-welded boundary, and thus it is possible to obtain a solar battery module having excellent bonding reliability and excellent photoelectric conversion efficiency.

Furthermore, because resin containing organic acid or using organic acid in a curing agent is used as the resin, it is possible to perform solder welding without using any flux, and thus the solar battery element can be prevented from being damaged, and thus it is possible to easily manufacture a structure covering the side surface of the solder-welded portion.

### BRIEF DESCRIPTION OF DRAWINGS

FIG. 1 is a cross-sectional view of a configuration of a solar battery module according to a first embodiment of the present invention.

FIGS. 2(a) and (b) depict a configuration of a solar battery element according to the first embodiment.

FIG. 3 is an explanatory diagram of a method of connecting a collector electrode formed on a light-receiving surface of a solar battery element and a wiring member, and is a plan view of a state where the wiring member is bonded on the collector electrode as viewed from the light-receiving surface side.

FIGS. 4(a), (b) and (c) are cross-sectional views for explaining a method of connecting a collector electrode and a wiring member, and are cross-sectional views of relevant parts along a line A-A shown in FIG. 3.

FIG. 5 is a cross-sectional view for explaining a method of connecting a collector electrode and a wiring member, and is an enlarged cross-sectional view of a portion shown in FIG. 4.

FIGS. 6(a), (b) and (c) are cross-sectional views of a method of manufacturing the solar battery module according to the first embodiment.

FIGS. 7(a), (b) and (c) are cross-sectional views of another method of connecting a collector electrode and a wiring member.

### DESCRIPTION OF EMBODIMENTS

Exemplary embodiments of a solar battery module and a manufacturing method thereof according to the present invention will be explained below in detail with reference to the accompanying drawings. The present invention is not limited to the following descriptions and can be modified as appropriate without departing from the scope of the present invention. In addition, in the drawings explained below, for easier understanding, scales of respective members may be different from those of actual products. The same holds true for the relationships between respective drawings. Furthermore, identical members and corresponding members are denoted by like reference signs and redundant explanations thereof may be omitted.

### First Embodiment

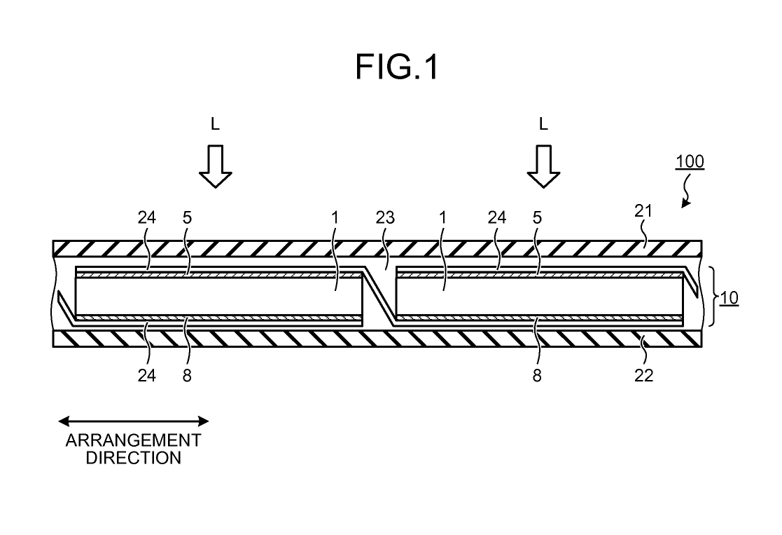

FIG. 1 is a cross-sectional view of a configuration of a solar battery module 100 according to a first embodiment of the present invention. As shown in FIG. 1, the solar battery module 100 according to the first embodiment includes a solar battery string 10 in which solar battery elements 1 are connected to each other by a wiring member 24, a light-receiving-surface-side protecting member 21, a rear-surface-side protecting member 22, and a sealing member 23. The solar battery string 10 is sealed in the sealing member 23 that is sandwiched between the light-receiving-surface-side protecting member 21 arranged on a side of a front surface (a light-receiving surface side) of the solar battery module 100 and the rear-surface-side protecting member 22 that is arranged on an opposite side (a rear surface side) of the light-receiving surface of the solar battery module 100. Light L is incident on the solar battery module 100 from a side of the light-receiving-surface-side protecting member 21.

The light-receiving-surface-side protecting member 21 is formed of a material that is transparent to light, and is arranged on the light-receiving surface side of the solar battery string 10 where the sunlight is received, to protect the light-receiving surface side of the solar battery string 10. For example, glass or transparent plastic is used as the material for the light-receiving-surface-side protecting member 21. The rear-surface-side protecting member 22 is arranged on a surface (a rear surface) of opposite side of the light-receiving surface of the solar battery string 10, to protect the rear surface side of the solar battery string 10. For example, a transparent film such as PET or a laminated film sandwiching an Al foil is used as the material for the rear-surface-side protecting member 22.

The sealing member 23 is arranged between the solar battery string 10 and the light-receiving-surface-side protecting member 21 and between the solar battery string 10 and the rear-surface-side protecting member 22. For example, transparent resin such as EVA, silicon, or urethane is used as the material for the sealing member 23.

A configuration of the solar battery string 10 is explained below. As shown in FIG. 1, the solar battery string 10 includes the solar battery elements 1 arranged in a predetermined arrangement direction and the wiring member 24. The solar battery elements 1 are arranged in the predetermined arrangement direction by being separated by a predetermined distance therebetween. The solar battery elements 1 adjacent to each other are electrically connected in series by the wiring member 24. Although two solar battery elements 1 of the are shown in FIG. 1, the number of the solar battery elements 1 that are electrically connected to each other is not limited thereto, and it is possible to have a configuration in which a larger number of the solar battery elements 1 are provided.

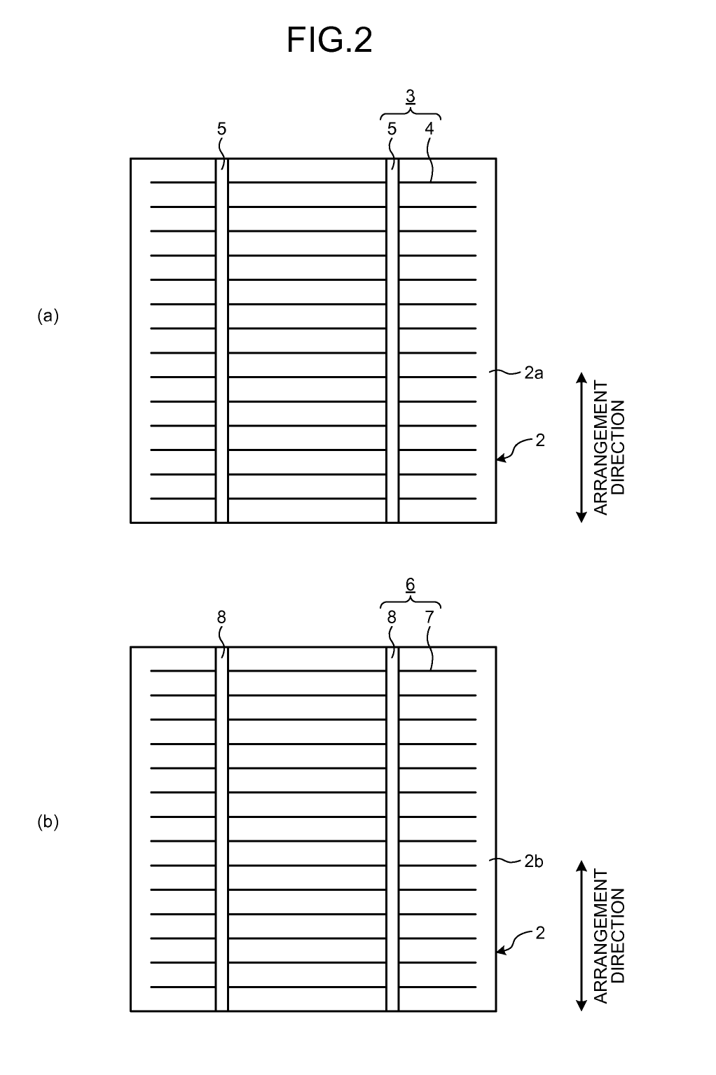

FIG. 2 depict a configuration of the solar battery element 1 according to the first embodiment. FIG. 2(a) is a plan view of the solar battery element 1 as viewed from the light-receiving surface side. FIG. 2(b) is a plan view of the solar battery element 1 as viewed from the rear surface side. The solar battery element 1 includes a photoelectric conversion portion 2. Collector electrodes 5 and 8 for bonding with the wiring member 24 are formed on the light-receiving surface side and the rear surface side of the photoelectric conversion portion 2.

A front surface electrode 3 that is electrically connected to the photoelectric conversion portion 2 is provided on a side of a light-receiving surface 2a of the photoelectric conversion portion 2. The front surface electrode 3 includes a thin wire electrode 4 for collecting a photo-generated carrier from the photoelectric conversion portion 2 and the collector electrode 5 for collecting the photo-generated carrier from the thin wire electrode 4. A plurality of thin wire electrodes 4 are arranged next to each other on the side of the light-receiving surface 2a of the photoelectric conversion portion 2. The collector electrode 5 is provided to be electrically connected to the thin wire electrode 4 to be substantially perpendicular to the thin wire electrode 4. The thin wire electrode 4 and the collector electrode 5 are electrically connected to the photoelectric conversion portion 2 at their respective bottom surface portions.

The thin wire electrode 4 is formed by sintering an electrically conductive paste including glass or resin as a binder and electrically conductive particles of silver (Ag) as a filler, for example. An electrode width of the thin wire electrode 4 is set as narrow as several tens of micrometers, for example, in order to increase a light-receiving area of the collector electrode 5. Similarly to the thin wire electrode 4, the collector electrode 5 is formed by sintering an electrically conductive paste including glass or resin as a binder and electrically conductive particles of Ag as a filler, for example. An electrode width of the collector electrode 5 is about 1 to 2 millimeters, for example. In the present embodiment, each of the thin wire electrode 4 and the collector electrode 5 is formed by sintering an electrically conductive paste including glass as a binder and Ag as a filler. Although an electrode obtained by sintering the electrically conductive particles with the binder is used as the collector electrode 5 in the present embodiment, the collector electrode 5 is not limited thereto, and the collector electrode 5 can be also formed by using a thin-film deposition technique such as a sputtering or plating method.

On the other hand, a rear surface electrode 6 that is electrically connected to the photoelectric conversion portion 2 is provided on a side of a rear surface 2b of the photoelectric conversion portion 2. Similarly to the front surface electrode 3, the rear surface electrode 6 includes a thin wire electrode 7 for collecting the photo-generated carrier from the photoelectric conversion portion 2 and the collector electrode 8 for collecting the photo-generated from the thin wire electrode 7. A plurality of thin wire electrodes 7 are arranged next to each other on the side of the rear surface 2b of the photoelectric conversion portion 2. The collector electrode 8 is provided to be electrically connected to the thin wire electrode 7 to be substantially perpendicular to the thin wire electrode 7. The thin wire electrode 7 and the collector electrode 8 are electrically connected to the photoelectric conversion portion 2 at their respective bottom surface portions. The structure on the side of the rear surface 2b is not limited to the structure mentioned above, and it can be a structure in which the entire surface of the rear surface of the photoelectric conversion portion 2 is formed as the electrode, and when the entire surface of the rear surface is formed as the electrode, it is not necessary to provide the thin wire electrode 7.

The wiring member 24 is bonded with the collector electrode 5 formed on the light-receiving surface of one solar battery element 1 and the collector electrode 8 formed on the rear surface of the other solar battery element 1 adjacent to the one solar battery element 1, to electrically connect two adjacent solar battery elements 1. For example, an electrically conductive member such as copper or solder-plated copper can be used as the wiring member 24.

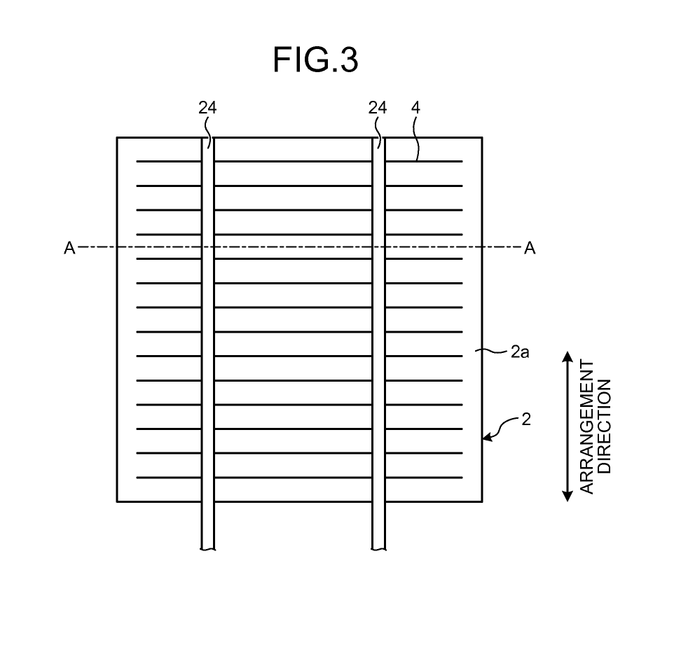

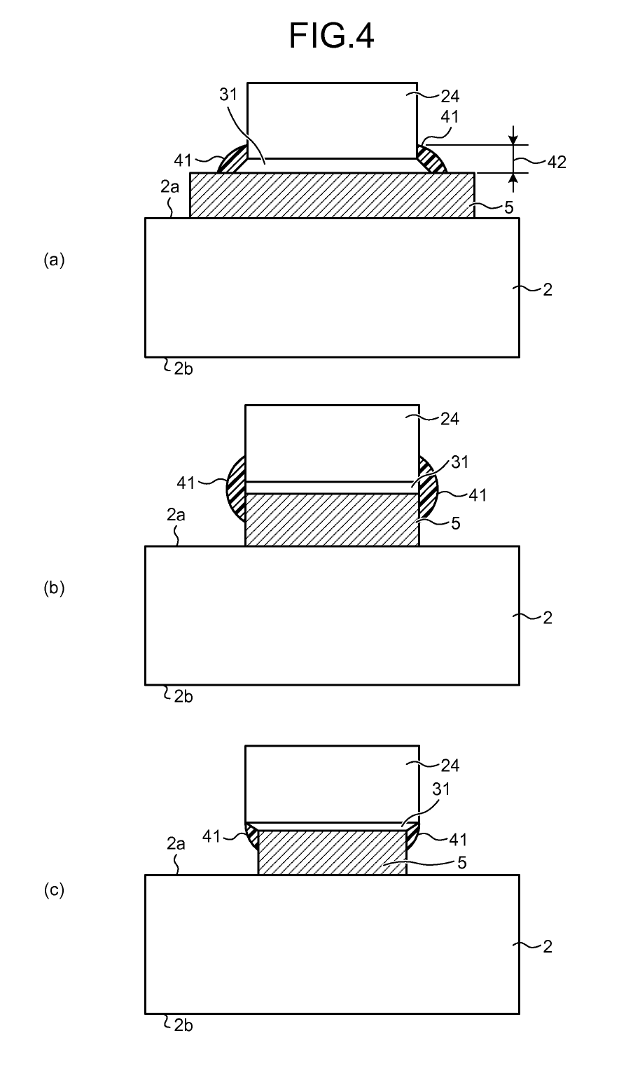

Next, a method of connecting the collector electrode 5 formed on the light-receiving surface 2a of the solar battery element 1 and the wiring member 24 is explained. FIG. 3 is an explanatory diagram of the method of connecting the collector electrode 5 formed on the light-receiving surface 2a of the solar battery element 1 and the wiring member 24, and is a plan view of a state where the wiring member 24 is bonded on the collector electrode 5 as viewed from the light-receiving surface side. FIG. 4 are cross-sectional views for explaining the method of connecting the collector electrode 5 and the wiring member 24, and are cross-sectional views of relevant parts along a line A-A shown in FIG. 3.

As shown in FIGS. 4(a), (b), and (c), the collector electrode 5 and the wiring member 24 are solder-welded by solder 31. The solder welding is welding in which the solder 31 that is melted by heating is metal joined with the wiring member 24, and an alloy layer (not shown) exists on a boundary between the solder 31 and the collector electrode 5. For example, when the solder is SnAgCu and collector electrode 5 is Ag, an alloy layer of Sn and Ag is formed. Furthermore, the welding of a side surface portion in a longitudinal direction of the collector electrode 5 and the wiring member 24 is reinforced by a thermosetting resin 41. FIG. 4(a) depicts a case where the width of the wiring member 24 is smaller than the width of the collector electrode 5. The thermosetting resin 41 covers the boundary between the solder 31 and the wiring member 24 and the boundary between the solder 31 and the collector electrode 5. FIG. 4(b) depicts a case where the width of the wiring member 24 is same as the width of the collector electrode 5. The thermosetting resin 41 covers a boundary between the solder 31 and the wiring member 24 and the boundary between the solder 31 and the collector electrode 5. FIG. 4(c) depicts a case where the width of the wiring member 24 is larger than the width of the collector electrode 5. The thermosetting resin 41 covers the boundary between the solder 31 and the wiring member 24 and the boundary between the solder 31 and the collector electrode 5. In FIG. 4(a), it is important that a wetted height 42 of the thermosetting resin 41 on the side surface of the wiring member 24 be lower than the top of wiring member 24 in terms of the bonding reliability. The wetted height 42 mentioned here indicates how much the thermosetting resin 41 wets the wiring member 24, which is the height from the boundary between the collector electrode 5 and the solder 31.

When the amount of the thermosetting resin 41 that covers the side surface of the solder-welded portion of the wiring member 24 in the longitudinal direction is large, the thermosetting resin 41 wets the side surface of the wiring member 24 in an upward direction so that the wetted height is increased, and at the same time, the thermosetting resin 41 is spread to the light-receiving surface 2a of the solar battery element 1. When the thermosetting resin 41 is spread to the light-receiving surface 2a, a light-receiving amount is decreased so that the efficiency is decreased, and thus it is required to suppress the spread of the thermosetting resin 41 to the light-receiving surface 2a. To this end, it is required to decrease the wetted height 42 on the wiring member 24 because it is required to decrease the amount of the thermosetting resin 41. Also in order to decrease a stress of a solder-welded portion 31a, it is preferred that the wetted height 42 on the wiring member 24 is equal to or smaller lower than a half of the thickness of the wiring member 24.

Although the thermosetting resin 41 covers the boundary between the solder 31 and the collector electrode 5, which as a large thermal expansion difference, and the boundary between the solder 31 and the wiring member 24 in the present embodiment, as long as the thermosetting resin 41 covers at least the boundary between the solder 31 and the collector electrode 5, which as a large thermal expansion difference, the present invention can sufficiently exert its effects.

In this manner, the collector electrode 5 and the wiring member 24 are welded by the solder 31. Furthermore, the side surface portions of the collector electrode 5 and the wiring member 24 in the longitudinal direction are covered by the thermosetting resin 41, to reinforce the bonding. Therefore, in the solar battery string 10, the bonding strength between the collector electrode 5 and the wiring member 24 is improved and a sufficient mechanical strength can be obtained, as compared to a case where the collector electrode 5 and the wiring member 24 are welded only with solder or resin.

In a case where the collector electrode 5 and the wiring member 24 are bonded only with solder, when a temperature cycle is applied, the stress is concentrated on the boundary between the collector electrode 5 and the solder 31, which has a large thermal expansion difference, and cracks are generated. However, in the solar battery string 10, because the side surface portions of the collector electrode 5 and the wiring member 24 in the longitudinal direction are reinforced by the thermosetting resin 41, it is possible to suppress the generation of cracks from the boundary between the wiring member 24 or the collector electrode 5 and solder due to the temperature cycle mentioned above. This makes it possible to improve the bonding reliability as compared to the bonding only with solder.

In a case where the collector electrode 5 and the wiring member 24 are bonded only by a resin adhesive, an electrical contact resistance between the wiring member and the collector electrode is increased to about ten times of that of the case of using solder. Furthermore, in the case of bonding only by a resin adhesive, because the electrical connection is obtained by the electrically conductive particles, the electrical connection area is decreased so that an allowable current is decreased, which decreases the power generation efficiency and the photoelectric conversion efficiency. Further, in the case of bonding only by a resin adhesive, the bonding strength between the wiring member and the collector electrode is as small as about 1/10 of that of the case of using solder, the bonding reliability is degraded.

However, in the present invention, because the collector electrode 5 and the wiring member 24 are bonded by using both the resin adhesive and solder, the electrical contact resistance can be decreased as compared to the case of bonding only by a resin adhesive, and at the same time, the bonding strength is stronger than the resin, and thus it is possible to improve the bonding reliability.

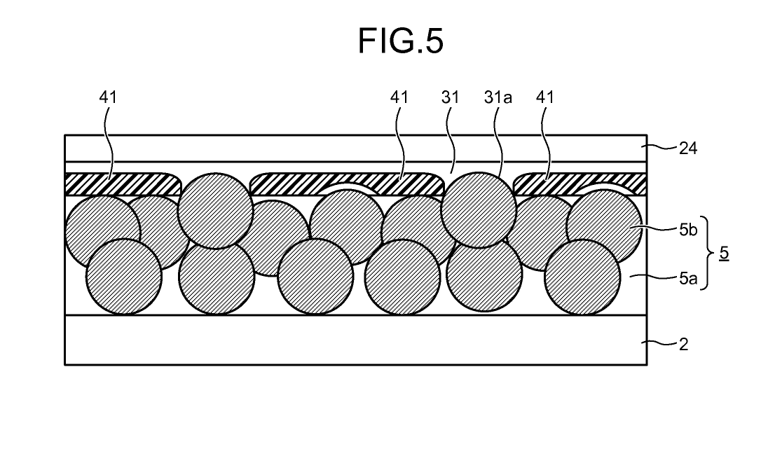

Next, a case where the electrode formed by sintering the electrically conductive particles with a binder such as glass or resin is used as the collector electrode 5 is explained. FIG. 5 is a cross-sectional view for explaining the method of connecting the collector electrode 5 and the wiring member 24, and is an enlarged cross-sectional view of a portion of the center of the bonded portion shown in FIG. 4. As shown in FIG. 5, in the collector electrode 5, a binder 5a covers a surface layer of an Ag particle 5b, so that exposure of the Ag particle 5b is decreased. A side surface of a bonded portion (the solder-welded portion 31a) between the solder 31 and the Ag particle 5b is bonded with the thermosetting resin 41. Because the solder-welded portion 31a between the solder 31 and the Ag particle 5b is metal joined, an alloy layer (not shown) of the solder and Ag is formed. When Sn-based solder such as Sn—Ag—Cu, Sn—Ag, or Sn—Cu is used as the solder 31, the alloy layer of the solder and Ag becomes an alloy layer of Sn and Ag. Although Ag is used as the collector electrode 5 in this example, as long as a metal wets the solder of Cu, Au, and the like, it is possible to obtain the same effects.

In this manner, the collector electrode 5 and the wiring member 24 are welded by the solder 31 at the solder-welded portion 31a. Furthermore, the collector electrode 5 and the wiring member 24 are bonded by solder and resin at a portion other than the solder-welded portion 31a. Therefore, in the solar battery string 10, the bonding strength between the collector electrode 5 and the wiring member 24 is improved and a sufficient mechanical strength can be obtained as compared to the case where the collector electrode 5 and the wiring member 24 are bonded only with solder or resin.

In a case where the collector electrode 5 and the wiring member 24 are welded only with solder, when a temperature cycle is applied, the stress is concentrated on an end surface of the solder-welded portion starting from a portion where the binder is exposed so that the solder-welding is not performed. However, in the solar battery string 10, because the portion other than the solder-welded portion 31a is reinforced and bonded by resin, it is possible to suppress the generation of cracks of solder due to the temperature cycle mentioned above. This makes it possible to obtain high connection reliability.

In a case where the collector electrode 5 and the wiring member 24 are bonded only by a resin adhesive, the electrical contact resistance between the wiring member and the collector electrode is increased to about ten times of that of the case of using solder. Furthermore, in the case of the bonding only by a resin adhesive, because the electrical connection is obtained by the electrically conductive particles, the electrical connection area is decreased so that an allowable current is decreased, which decreases the power generation efficiency and the photoelectric conversion efficiency. Further, in the case of bonding only by a resin adhesive, the bonding strength between the wiring member and the collector electrode is as small as about 1/10 of that of the case of using solder, the bonding reliability is degraded.

However, in the solar battery string 10, because the collector electrode 5 and the wiring member 24 are bonded by using both the resin adhesive and solder, it is possible to suppress the generation of such a problem, and thus it is possible to achieve excellent photoelectric conversion efficiency and connection reliability.

Although the bonding of the collector electrode 5 and the wiring member 24 on the side of the light-receiving surface 2a of the solar battery element 1 has been explained in FIGS. 4 and 5, the bonding of the collector electrode 8 and the wiring member 24 on the side of the rear surface 2b of the solar battery element 1 is same as the bonding of the collector electrode 5 and the wiring member 24, so that improvement of the mechanical strength, connection reliability, and the photoelectric conversion efficiency is achieved.

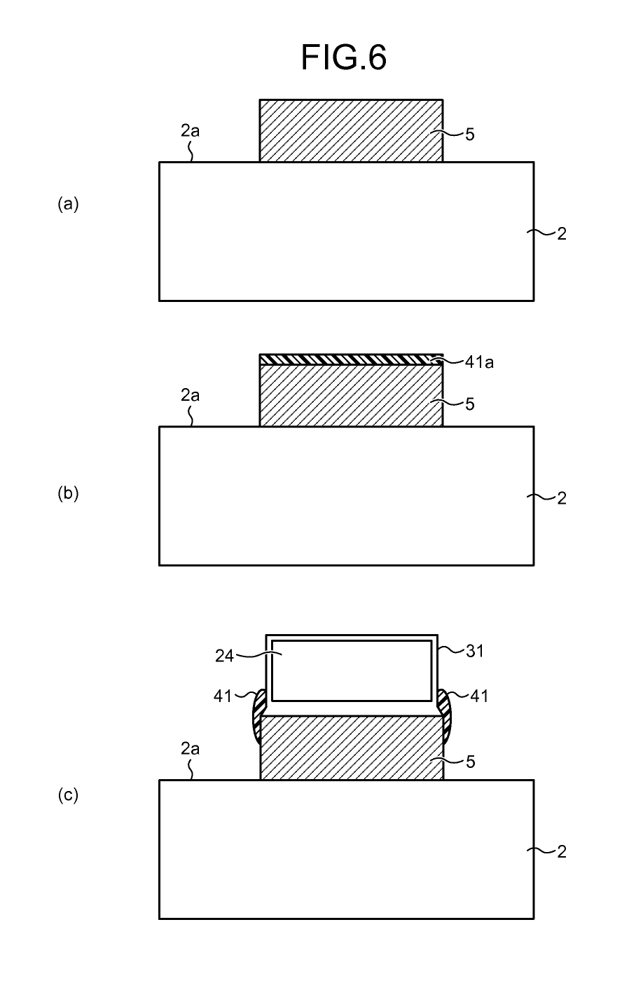

Next, a method of manufacturing the solar battery module 100 according to the first embodiment configured as described above is explained with reference to FIG. 6. FIG. 6 are cross-sectional views of the method of manufacturing the solar battery module 100 according to the first embodiment. In FIG. 6, the method is shown focusing on only the side of the light-receiving surface 2a of the solar battery element 1.

First, the solar battery element 1 shown in FIG. 2 is manufactured by using a known method. The collector electrode 5 is formed on the side of the light-receiving surface 2a of the solar battery element 1 (FIG. 6(a)). Subsequently, thermosetting resin 41a before thermal-curing is arranged on the collector electrode 5 (FIG. 6(b)). For example, a thermal-curing epoxy resin composition is used as the thermosetting resin 41a, and thermal-curing epoxy resin containing epoxy resin and organic acid or using a curing agent of organic acid is used as the thermal-curing epoxy resin composition. The curing agent containing the organic acid includes, for example, a phenol curing agent, an acid anhydride curing agent, and a carboxylic acid curing agent, which can include a single agent or a plurality of agents. The thermosetting resin 41a can be a liquid type or a film of a half-cured state (a B stage).

Next, the wiring member 24 of which the outer circumferential surface is plated with the solder 31 is positioned on the collector electrode 5. In a state where the wiring member 24 is brought into contact with the collector electrode 5, heat is applied to a temperature equal to or higher than a melting point of the solder 31. The bonding surfaces of the wiring member 24 and the collector electrode 5 are welded by the solder 31, and as shown in FIG. 5, the solder-welded portion 31a is formed. Furthermore, the side surface of the solder-welded portion 31a is covered with the thermosetting resin 41 that is obtained by curing the thermosetting resin 41a, so that the bonding of the wiring member 24 and the collector electrode 5 by the solder 31 is reinforced. Further, the side surface portions of the collector electrode 5 and the wiring member 24 in the longitudinal direction are covered and bonded with the thermosetting resin 41 sticking out from between the collector electrode 5 and the wiring member 24. The wiring member 24 and the collector electrode 5 are then bonded by the solder 31 and the thermosetting resin 41 (FIG. 6(C)).

Due to the sticking out of the thermosetting resin 41, the wetted height 42 of the thermosetting resin 41 on the wiring member 24, which is formed to cover the side surface portions of the collector electrode 5 and the wiring member 24 in the longitudinal direction is set lower than the wiring member 24. If the wetted height 42 is higher than the wiring member 24, because the thermal expansion of the thermosetting resin 41 is larger than the wiring member 24, it operates to peel the wiring member 24, which may degrade the bonding reliability. Furthermore, at the same time as the thermosetting resin 41 that sticks out wets the wiring member 24, the thermosetting resin 41 is spread to the light-receiving surface 2a of the solar battery element 1 via the collector electrode 5. If the thermosetting resin 41 is spread on the light-receiving surface 2a, the light-receiving efficiency may be degraded, and thus it is preferred that the wetted height 42 on the wiring member 24 is equal to or lower than a half of the thickness of the wiring member 24 from the solder-welded boundary.

In the process of the thermal-curing of the thermosetting resin 41a, the thermal-curing epoxy resin composition containing organic acid or using organic acid in a curing agent operates to reduce and remove an oxide film on the surface of the solder 31. Therefore, a flux for removing the oxide film is not needed, so that the flux does not need to be applied in advance at the time of solder welding, and thus the bonding can be performed with high productivity at a low cost.

Although the wiring member 24 of which the outer circumferential surface is plated with the solder 31 is used in this example, for example, other methods can be alternatively employed, such as plating the collector electrode 5 with the solder 31.

In the above explanations, a case of bonding the collector electrode 5 and the wiring member 24 on the side of the light-receiving surface 2a of the solar battery element 1 has been explained. However, the collector electrode 8 and the wiring member 24 on the side of the rear surface 2b of the solar battery element 1 can be also bonded in the same manner as the above explanations.

The collector electrode 5 formed on the light-receiving surface 2a of one solar battery element 1 and the collector electrode 8 formed on the rear surface 2b of the other solar battery element 1 are then electrically connected by the wiring member 24. By repeating such a connection, the solar battery string 10 in which the solar battery elements 1 are electrically connected to each other is formed.

Thereafter, by using a known method, the solar battery string 10 is sealed in the sealing member 23 that is sandwiched between the light-receiving-surface-side protecting member 21 and the rear-surface-side protecting member 22. By performing the processes described above, the solar battery module 100 according to the first embodiment is obtained.

According to the first embodiment described above, the collector electrode and the wiring member of the solar battery element 1 are welded by solder. Furthermore, the side surface portions of the collector electrode 5 and the wiring member 24 in the longitudinal direction are covered by the thermosetting resin 41 so that the bonding of the collector electrode and the wiring member is reinforced. Further, because the side surface of the solder-bonded portion 31a is covered with the thermosetting resin 41, the collector electrode and the wiring member are bonded and reinforced with the thermosetting resin 41. With this configuration, a solar battery module having excellent mechanical strength, bonding reliability, and photoelectric conversion efficiency can be obtained.

Because the thermal-curing epoxy resin composition containing organic acid or using a curing agent of organic acid shows a flux activity (a reduction of a solder oxide film) by the resin composition itself, excellent solder welding can be obtained, and thus a solar battery module having high connection reliability can be obtained.

Furthermore, because solder welding and resin reinforcement of the solder-welded portion can be performed simultaneously without using any flux, a solar battery module with high productivity can be obtained at a low cost.

The configuration of the solar battery element 1 is not limited to the configuration mentioned above, and as long as the collector electrode is formed on the light-receiving surface and the rear surface, various configurations can be applied.

### Second Embodiment

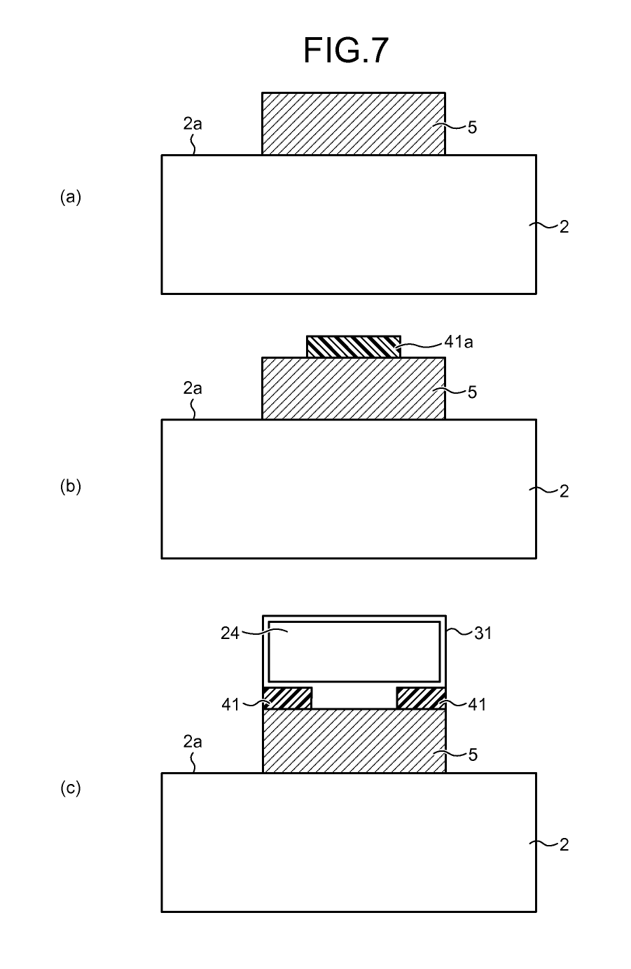

In a second embodiment of the present invention, a modification of the method of manufacturing the solar battery module according to the first embodiment is explained. FIG. 7 are cross-sectional views of another method of connecting a collector electrode and a wiring member. FIG. 7 correspond to FIG. 6, and members identical to those shown in FIG. 6 are denoted by like reference signs.

First, similarly to the first embodiment, the solar battery element 1 shown in FIG. 2 is manufactured by using a known method. The collector electrode 5 is formed on the side of the light-receiving surface 2a of the solar battery element 1 (FIG. 7(a)). Subsequently, the thermosetting resin 41a before thermal-curing is arranged on the collector electrode 5 (FIG. 7(b)). The width of the thermosetting resin 41a is set smaller than the width of the collector electrode 5. The width of the thermosetting resin 41a mentioned here is a width in a direction of a short side of the collector electrode 5. By reducing the width of the thermosetting resin 41a arranged on the collector electrode 5, it is possible to suppress the sticking out of the thermosetting resin 41 from the collector electrode 5 when bonding the wiring member 24, which makes it possible to suppress the thermosetting resin 41 sticks out to decrease the light-receiving surface area.

Similarly to the case of the first embodiment, the thermosetting resin 41a is the thermal-curing epoxy resin containing organic acid or using a curing agent of organic acid, such as a phenol curing agent, an acid anhydride curing agent, and a carboxylic acid curing agent, and the thermosetting resin 41a can be a liquid type or a film of a half-cured state (a B stage).

Next, the wiring member 24 of which the outer circumferential surface is plated with the solder 31 is positioned on the collector electrode 5. In a state where the wiring member 24 is brought into contact with the collector electrode 5, heat is applied to a temperature equal to or higher than a melting point of the solder 31. The bonding surfaces of the wiring member 24 and the collector electrode 5 are bonded by the solder 31, and as shown in FIG. 5, the solder-welded portion 31a is formed. Furthermore, the side surface of the solder-welded portion 31a is covered with the thermosetting resin 41 that is obtained by curing the thermosetting resin 41a, so that the bonding of the wiring member 24 and the collector electrode 5 by the solder 31 is reinforced.

On the other hand, at the side surface portions of the collector electrode 5 and the wiring member 24 in the longitudinal direction, the thermosetting resin 41 does not stick out from between the collector electrode 5 and the wiring member 24. Therefore, the thermosetting resin 41 covers and bonds surroundings of the solder 31 only in an area between the collector electrode 5 and the wiring member 24, to reinforce the bonding of the collector electrode 5 and the wiring member 24. The wiring member 24 and the collector electrode 5 are then welded by the solder 31 and the thermosetting resin 41 (FIG. 7(C)). In this case, the light-receiving surface can be increased while securing the bonding reliability, and thus it is possible to improve the photoelectric conversion efficiency.

Also in the second embodiment, in the process of the thermal-curing of the thermosetting resin 41a, the thermal-curing epoxy resin composition containing organic acid or using organic acid in a curing agent operates to reduce and remove the oxide film on the surface of the solder 31. Therefore, a flux for removing the oxide film is not needed, so that the bonding can be performed with high productivity.

Although the wiring member 24 of which the outer circumferential surface is plated with the solder 31 is used in this example, for example, other methods can be alternatively employed, such as plating the collector electrode 5 with the solder 31.

In the above explanations, the case of bonding the collector electrode 5 and the wiring member 24 on the side of the light-receiving surface 2a of the solar battery element 1 has been explained. However, the collector electrode 8 and the wiring member 24 on the side of the rear surface 2b of the solar battery element 1 can be also bonded in the same manner as the above explanations.

The collector electrode 5 formed on the light-receiving surface 2a of one solar battery element 1 and the collector electrode 8 formed on the rear surface 2b of the other solar battery element 1 are then electrically connected by the wiring member 24. By repeating such a connection, the solar battery string 10 in which the solar battery elements 1 are electrically connected to each other is formed.

Thereafter, by using a known method, the solar battery string 10 is sealed in the sealing member 23 that is sandwiched between the light-receiving-surface-side protecting member 21 and the rear-surface-side protecting member 22. By performing the processes described above, the solar battery module is obtained.

According to the second embodiment described above, similarly to the case of the first embodiment, the collector electrode and the wiring member of the solar battery element 1 are welded by the solder 31. Furthermore, because the side surface of the solder-welded portion 31a is covered with the thermosetting resin 41, the collector electrode and the wiring member are bonded and reinforced with the thermosetting resin 41. Further, the side surface portion of the solder 31 between the collector electrode 5 and the wiring member 24 in the longitudinal direction is covered with the thermosetting resin 41 so that the bonding of the wiring member 24 and the collector electrode 5 with the solder 31 is reinforced. With this configuration, a solar battery module having excellent mechanical strength, bonding reliability, and photoelectric conversion efficiency can be obtained.

According to the second embodiment, by the thermosetting resin 41 covering the side surface of the solder welding without sticking out to the side surface portions of the collector electrode 5 and the wiring member 24 in the longitudinal direction, the bonding of the wiring member 24 and the collector electrode 5 by the solder welding can be reinforced. With this configuration, the light-receiving surface can be increased while securing the bonding reliability, and thus it is possible to further improve the photoelectric conversion efficiency.

Because the thermal-curing epoxy resin composition using a curing agent of organic acid shows a flux activity (a reduction of a solder oxide film) by the resin composition itself, excellent solder welding can be achieved, and thus a solar battery module having high connection reliability can be obtained.

Furthermore, because solder welding and resin reinforcement of the solder-welded portion 31a can be performed simultaneously without using any flux, a solar battery module with high productivity can be obtained at a low cost.

### INDUSTRIAL APPLICABILITY

As described above, the solar battery module according to the present invention is useful for realizing a solar battery module having excellent mechanical strength and bonding reliability between a wiring member and an electrode and excellent photoelectric conversion efficiency.

### REFERENCE SIGNS LIST

1 solar battery element
2 photoelectric conversion portion
2a light-receiving surface
2b rear surface
3 front surface electrode
4 thin wire electrode
5 collector electrode
5a binder
5b Ag particle
6 rear surface electrode
7 thin wire electrode
8 collector electrode
10 solar battery string
21 light-receiving-surface-side protecting member
22 rear-surface-side protecting member
23 sealing member
24 wiring member
31 solder
31a solder-welded portion
41 thermosetting resin
41a thermosetting resin before thermal-curing
42 wetted height of thermosetting resin on wiring member
100 solar battery module
L Light

1. A solar battery module comprising a plurality of solar battery elements each including electrodes that are electrically connected by an electrically conductive wiring member, wherein
the electrode and the wiring member are welded by solder on the electrode, resin is arranged while covering a side surface of a welded portion between the solder and the electrode and a side surface of the wiring member, and a wetted height of the resin on the wiring member, which is a height from a boundary between the electrode and the solder, is lower than a top surface of the wiring member.

2. The solar battery module according to claim 1, wherein the resin is arranged while further covering a side surface of a welded portion between the solder and the wiring member.

3. The solar battery module according to claim 1, wherein the resin is thermosetting resin containing organic acid or using a curing agent of organic acid.

4. A method of manufacturing a solar battery module including a plurality of solar battery elements each including electrodes that are electrically connected by an electrically conductive wiring member, the method comprising:
a first step of arranging thermosetting resin containing organic acid or using a curing agent of organic acid and solder between the electrode and the wiring member; and
a second step of welding the electrode and the wiring member by the solder by pressurizing the electrode and the wiring member against each other and applying heat of a temperature equal to or higher than a melting point of the solder, and covering a side surface of a welded portion of the electrode and the solder and a side surface of the wiring member by the thermosetting resin sticking out from between the electrode and the wiring member.

5. The method of manufacturing a solar battery module according to claim 4, wherein
at the second step, the thermosetting resin covers a side surface of a bonded portion between the solder and the wiring member.
